(19) United States
(12) Patent Application Publication
(10) Pub. No.: US 2025/0131138 A1
(43) Pub. Date: Apr. 24, 2025

(54) CONTEXTUAL RECOMMENDATIONS FOR THREE-DIMENSIONAL DESIGN SPACES

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/895,918

(22) Filed: Sep. 25, 2024

Related U.S. Application Data
(60) Provisional application No. 63/592,874, filed on Oct. 24, 2023.

(51) Int. Cl. G06F 30/12

(52) U.S. Cl. CPC G06F 30/12

(57) ABSTRACT

In various embodiments, a computer-implemented method for generating recommendations for a generative design, comprises receiving a selection of a prompt volume within a design space, wherein the design space is generated by a design exploration application, and the prompt volume defines a sphere of influence within the prompt volume, identifying one or more design objects within the prompt volume, generating a plurality of candidate actions associated with the one or more design objects, and displaying, within a recommendation window included in the design space, at least one candidate action from the plurality of candidate actions.

### CROSS-REFERENCE TO RELATED APPLICATIONS

This application claims priority benefit of the United States Provisional Patent Application titled “TECHNIQUES FOR SOFTWARE-BASED RECOMMENDATIONS,” filed on Oct. 24, 2023, and having Ser. No. 63/592,874, and United States Patent Application titled “SPATIALLY ARRANGED PROMPT VOLUMES TO GENERATE THREE-DIMENSIONAL DESIGNS,” filed on Apr. 29, 2024, and having Ser. No. 18/649,872. The subject matter of these related applications is hereby incorporated herein by reference.

### BACKGROUND

### Field of the Various Embodiments

The various embodiments relate generally to computer-aided design and artificial intelligence and, more specifically, to contextual recommendations for three-dimensional design spaces.

### Description of the Related Art

Design exploration for three-dimensional (3D) objects generally refers to a phase of a design process during which a designer generates and evaluates various design alternatives for one or more 3D objects within a larger 3D design project. As is well-understood in practice, manually generating multiple designs for even a relatively simple 3D object can be very labor-intensive and time-consuming. Because the time allocated for generating a design for a specific 3D object is usually limited, users typically produce only a small number of designs, which oftentimes reduces the overall quality of the final design. Accordingly, various conventional computer-aided design (CAD) applications have been developed that attempt to automate more fully how 3D objects are generated and evaluated.

One approach to automating how CAD applications generate and evaluate 3D objects involves implementing an artificial intelligence (AI) model, such as a generative machine learning model, to automatically synthesize a design in response to a prompt provided by the user. The prompt provided to the AI model is usually in the form of a design problem statement that specifies one or more design characteristics to which the generated design should adhere. The prompt can include any number of quantitative goals, physical objects, physical and functional constraints, and/or mechanical and geometric quantities that guide how the AI model should generate the design. The AI model responds to the prompt by executing various optimization algorithms to generate designs that satisfy the applicable design characteristics specified in the prompt. In some cases, the AI model generates a single design that the user selects and incorporates into the larger 3D design project. In other cases, the AI model generates numerous design alternatives and presents those design alternatives to a user within a design space. The user subsequently explores the design space, manually viewing and evaluating different design alternatives included in the design space in an attempt to select the best design alternative to incorporate into the larger 3D design project.

One drawback of the above approach is that conventional CAD applications typically provide limited, if any, feedback during the design process. For example, a conventional CAD application may provide recommendations to a designer for how to progress in completing a design. However, conventional CAD applications usually only provide high-level or generalized recommendations based on predetermined or preprogrammed actions, such as when a designer selects a given design tool for the first time, or based on a series of historical actions, such as when a designer completes the first steps in a known design workflow. Another drawback is that conventional CAD applications do not typically allow designers to request specific recommendations for an overall design or workflow. For example, a conventional CAD application typically analyzes an overall design when generating recommendations for a designer, but the designer oftentimes is not able to request recommendations for a particular component included in the overall design or to refine the more generalized recommendations that the CAD application generates. As a result, designers sometimes stop requesting recommendations from the CAD application and/or stop selecting the recommendations generated by the CAD application during the design process.

As the foregoing illustrates, what is needed in the art are more effective techniques for generating recommendations during a computer-aided design process.

### SUMMARY

In various embodiments, a computer-implemented method for generating recommendations for a generative design, comprises receiving a selection of a prompt volume within a design space, where the design space is generated by a design exploration application, and the prompt volume defines a sphere of influence within the prompt volume, identifying one or more design objects within the prompt volume, generating a plurality of candidate actions associated with the one or more design objects, and displaying, within a recommendation window included in the design space, at least one candidate action from the plurality of candidate actions.

At least one technical advantage of the disclosed techniques relative to the prior art is that the disclosed techniques can be used to identify specific objects within a design space and generate contextually-relevant recommendations associated with the identified objects. Thus, the design recommendation generated using the disclosed techniques are typically more specific and useful to a user and, accordingly, are more likely to be selected by the user, relative to the design recommendations generated using prior art techniques. In this regard, the disclosed techniques enable users to define spatial volumes within a design space that constrain the scope of the 3D objects. A design exploration application using such spatial volumes can identify the relevant portion of an overall design with greater precision and can generate recommendations that are more relevant to a particular 3D object or portion of an overall design. Further, by enabling a user to request recommendations for specific portions of an overall design, the user can complete specific portions of an overall design faster, reducing the overall design time for the user and increasing overall design quality relative to what can be achieved using prior art techniques. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 is an exemplar illustration of the design space and the prompt space of FIG. 2, according to various embodiments;

FIG. 4 is an exemplar illustration of a recommendation window based on contents of the prompt volume of FIG. 2, according to various embodiments;

FIG. 5 is an exemplar illustration of an updated recommendation window based on updated contents of the prompt volume of FIG. 2, according to various embodiments;

FIG. 6 is an exemplar illustration of a weighted prompt volume, according to various embodiments;

FIG. 7 sets forth a flow diagram of method steps for generating recommendations within a design space, according to various embodiments; and

FIG. 8 depicts one architecture of a system within which embodiments of the present disclosure may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

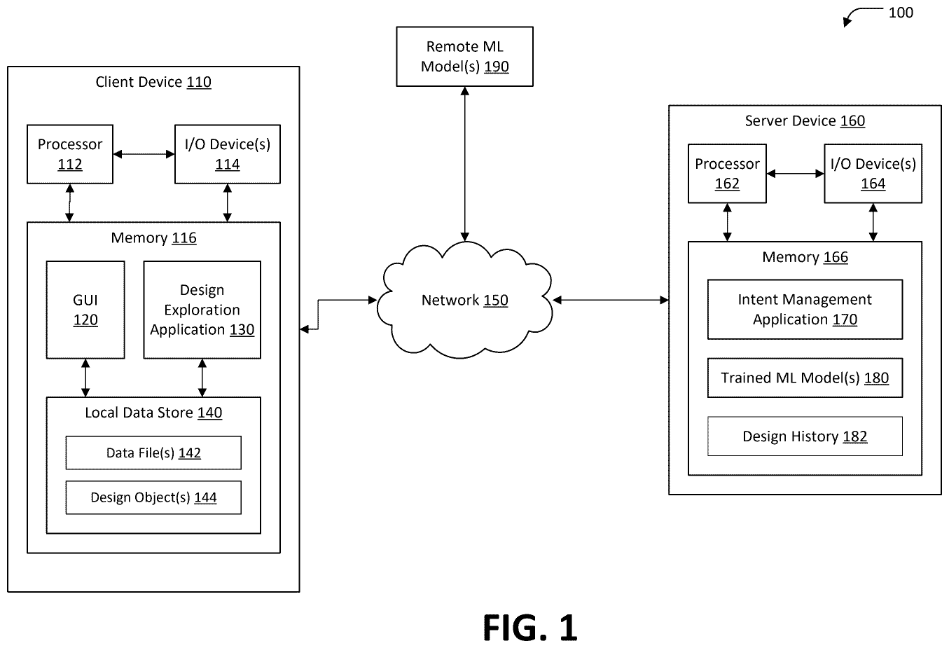

FIG. 1 is a conceptual illustration of a system 100 configured to implement one or more aspects of the various embodiments. As shown, in some embodiments, the system 100 includes, without limitation, a client device 110, a server device 160, and one or more remote machine learning (ML) models 190. The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142 and one or more design objects 144. The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate designs for one or more 3D objects. In operation, the design exploration application 130 causes one or more ML models 180, 190 to synthesize designs for a 3D object based on any number of goals and constraints. The design exploration application 130 then presents the designs as one or more design objects 144 to a user in the context of a design space. In some embodiments, the user can explore and modify the one or more design objects via the GUI 120. Additionally or alternatively, the user can also include at least one of the design objects 144 for use in additional design and/or manufacturing activities.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, and so forth. In some embodiments, the I/O devices 114 also includes devices configured to provide output, including, for example, a display device, a speaker, and so forth. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with a user via the GUI 120. In some embodiments, the design exploration application 130 and one or more separate applications (not shown) interact with the same user via the GUI 120. In various embodiments, the design exploration application 130 operates as a 3D design application to generate and modify an overall 3D design that includes one or more design objects 144. The design exploration application 130 interacts with a user via the GUI 120 in order to generate the one or more design objects 144 via direct user input (e.g., one or more tools to generate 3D objects, wireframe geometries, meshes, etc.) or via separate devices (e.g., the trained ML models 180, the remote ML models 190, separate 3D design applications, etc.). When generating the one or more design objects 144 via separate devices, the design exploration application 130 generates a prompt that effectively describes design-related intentions using one or more modalities (e.g., text, speech, images, etc.). The design exploration application 130 then causes the one or more of the ML models 180, 190 to operate on the generated prompt to generate a relevant design object 144. The design exploration application 130 receives the design object 144 from the one or more ML models 180, 190 and displays the design object 144 within the GUI 120. The user can select via the GUI 120 the design object 144 for use, such as incorporating the design object 144 in a larger 3D design.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. For example, the design exploration application 130 can generate contextual recommendation windows within the GUI 120. Some other examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

The local data store 140 is a part of storage in the client device 110 that stores one or more design objects 144 included in an overall 3D design and/or one or more data files 142 associated with 3D design. For example, an overall 3D design for a building can include multiple stored design objects 144, including design objects 144 separately representing doors, windows, fixtures, walls, appliances, and so forth. The local data store 140 can also include data files 142 relating to a generated overall 3D design (e.g., component files, metadata, etc.). Additionally or alternatively, the local data store 140 includes data files 142 related to generating prompts for transmission to the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth.

The design objects 144 include geometries, textures, images, and/or other components that the design exploration application 130 uses to generate an overall 3D design. In various embodiments, the geometry of a given design object refers to any multi-dimensional model of a physical structure, including CAD models, meshes, and point clouds, as well as circuit layouts, piping diagrams, free-body diagrams, and so forth. In some embodiments, the design exploration application 130 stores multiple design objects 144 for a given 3D design and stores multiple iterations of a given target object that the ML models 180, 190. For example, the user can form an initial prompt using the design exploration application 130 and receive a first generated design object 144(1) from the trained ML model 180(1), then refine the prompt and receive a second generated design object 144(2) from the trained ML model 180(1).

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more design objects 144. In operation, the server device 160 executes the intent management application 170 to process a prompt generated by the design exploration application 130, select one or more ML models 180, 190 trained to generate design objects 144 in response to the contents of the prompt, and input the prompt into the selected ML models 180, 190. Once the selected ML models 180, 190 generate the design objects 144 that are responsive to the prompt, the server device 160 transmits the generated design objects to the client device 110, where the generated design objects 144 are usable by the design exploration application 130.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and one or more trained ML models 180, and data (e.g., design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the intent management application 170 could be executed on the client device 110 and can communicate with the trained ML models 180 operating at the server device 160.

In various embodiments, the intent management application 170 receives a prompt from the design exploration application 130 and inputs the prompt into an applicable ML model 180, 190. In some embodiments, one or more of the ML models 180, 190 are trained to respond to specific types of inputs, such as a ML model that is trained to generate design objects from a specific combination of modalities (e.g., text and images). In such instances, the intent management application 170 processes a prompt to determine the modalities of the data that are included in the prompt and identifies one or more ML models 180, 190 that have been trained to respond to such a combination of modalities. Upon identifying the one or more ML models, the intent management application 170 selects an ML model (e.g., the trained ML model 180(1)) and inputs the prompt into the selected ML model 180(1).

The trained ML models 180 include one or more generative ML models that have been trained on a relatively large amount of existing data and optionally any number of results (e.g., design objects 144 and evaluations provided by the user) to perform any number and/or types of prediction tasks based on patterns detected in the existing data. In various embodiments, the remote ML models 190 are trained ML models that communicate with the server device 160 to receive prompts via the intent management application 170. In some embodiments, the trained ML model 180 is trained using various combinations of data from multiple modalities, such as textual data, image data, sound data, and so forth. The trained ML model 180 and/or the remote ML model 190 trained using at least two modalities of data are also referred to herein as a multimodal ML model. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate design objects from various combinations of modalities. Such combinations include text, a CAD object, a geometry, an image, a sketch, a video, an application state, an audio recording, etc.).

The design history 182 includes data and metadata associated with the one or more trained ML models 180 and/or the one or more remote ML models 190 generating design objects 144 in response to prompts provided by the design exploration application 130. In some embodiments, the design history 182 includes successive iterations of design objects 144 that a single ML model 180 generates in response to a series of prompts. Additionally or alternatively, the design history 182 includes multiple design objects 144 that were generated by different ML models 180, 190 in response to the same prompt. In some embodiments, the design history 182 includes feedback provided by the user for a given design object 144. In such instances, the server device 160 can use the design history 182 as training data to further train the one or more ML models 180. Additionally or alternatively, the design exploration application 130 can retrieve contents of the design history 182 and display the retrieved contents to the user via the GUI 120.

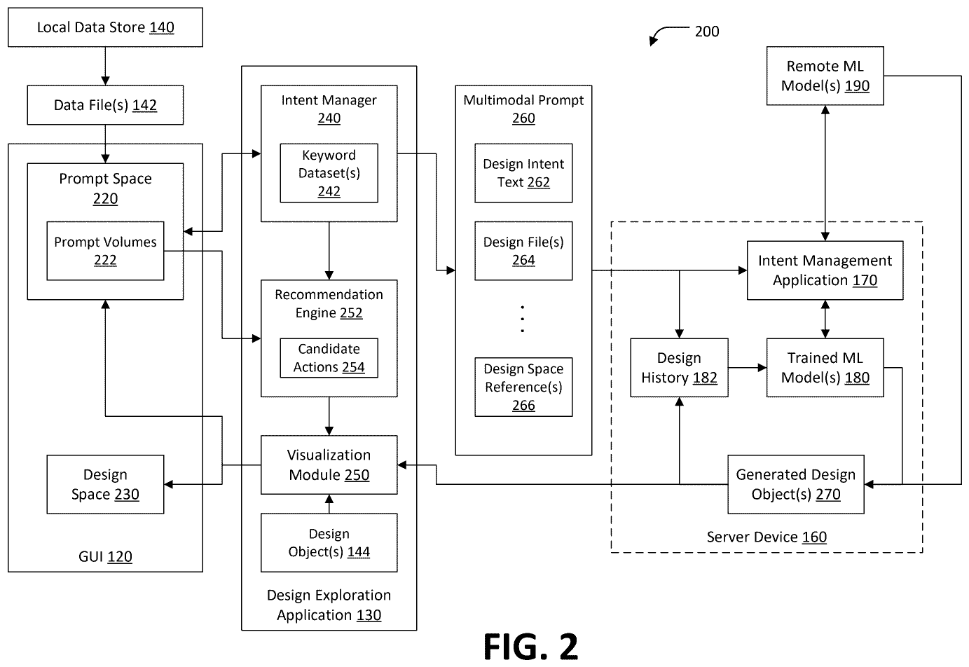

FIG. 2 is a more detailed illustration of the design exploration application 130 of FIG. 1, according to various embodiments. As shown, in some embodiments, the system 200 includes, without limitation, the GUI 120, the design exploration application 130, local data store 140, the one or more data files 142, the server device 160, the remote ML models 190, and a multimodal prompt 260. The GUI 120 includes, without limitation, a prompt space 220 including one or more prompt volumes 222, and a design space 230. The design exploration application 130 includes, without limitation, an intent manager 240 including one or more keyword datasets 242, the one or more design objects 144, a visualization module 250, and a recommendation engine 252. The server device 160 includes, without limitation, the intent management application 170, the one or more trained models 180, the design history 182, and one or more generated design objects 270. The multimodal prompt 260 includes, without limitation, design intent text 262, one or more design files 264, and one or more design space references 266.

For explanatory purposes only, the functionality of the design exploration application 130 is described herein in the context of exemplar interactive and linear workflows used to generate the generated design object 270 in accordance with user-based design-related intentions expressed during the workflow. The generated design object 270 includes, without limitation, one or more images, wireframe models, geometries, and/or meshes for use in a three-dimensional design, as well as any amount (including none) and/or types of associated metadata.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of generated design objects 270 associated with any target 3D object in a linear fashion, a nonlinear fashion, an iterative fashion, a non-iterative fashion, a recursive fashion, a non-recursive fashion, or any combination thereof during an overall process for generating and evaluating designs for that target 3D object. A target 3D object can include any number (including one) and/or types of target 3D objects and/or target 3D object components.

For example, in some embodiments, a generated design object 270 can be generated and displayed within the GUI 120 during a first iteration, any portion (including all) of the design object 270 can be selected via the GUI 120, and a first prompt multimodal prompt 260 can be set equal to the selected portion of the generated design object 270 to recursively generate a second generated design object 270 during a second iteration. In the same or other embodiments, the design exploration application 130 can display and/or re-display any number of GUI elements, generate and/or regenerate any amount of data, or any combination thereof any number of times and/in any order while generating each new generated design object 270.

In operation, the visualization module 250 of the design exploration application 130 provides the prompt space 220 and the design space 230 via the GUI 120. A user provides the contents for the multimodal prompt 260 via the prompt space 220. The design exploration application 130 processes the content to generate the multimodal prompt 260 and transmits the multimodal prompt 260 to the server device 160. The intent management application 170 identifies the modalities of the data included in the multimodal prompt 260 and identifies one or more trained ML models 180 and/or remote ML models 190 that have been trained to process the identified combination of modalities. The intent management application 170 inputs the multimodal prompt into one or more of the identified ML models 180, 190. The ML models 180, 190 respond to the multimodal prompt 260 by generating one or more design objects 270. The visualization module 250 receives the one or more generated design objects 270 and displays the one or more generated design objects 270 in the prompt space 220 and/or the design space 230. When the user invokes a request for a recommendation within the prompt volume 222, the recommendation engine 252 within the design exploration application 130 receives information associated with the prompt volume 222 as an input and causes the visualization module 250 to generate a recommendation window containing a set of candidate actions that are related to the contents of the prompt volume 222.

In various embodiments, the design space 230 is a virtual workspace that includes one or more renderings of design objects (e.g., geometries of the design objects 144 and/or the generated design objects 270) that form an overall 3D design. In some embodiments, the design space includes multiple design alternatives for the overall 3D design. For example, the design space 230 may graphically organize multiple 3D designs that include differing combinations of design objects 144, 270. In such instances, the user interacts with the GUI to navigate between design alternatives to quickly analyze tradeoffs between different design options, observe trends in design options, constrain the design space, select specific design options, and so forth.

The prompt space 220 is panel or volume in which a user can generate prompts, such as the multimodal prompt 260 and/or the one or more prompt volumes 222. In some embodiments, the prompt space is a panel, such as a window separate from the design space. Alternatively, in some embodiments, the prompt space 220 is a volume that is overlayed over at least a portion of the design space. In such instances, a user can invoke a prompt volume 222 and/or an input area for a multimodal prompt 260 at various locations within the design space 230.

The prompt volume 222 is a form of a prompt that executes operations within the boundaries of the volume. The prompt volume 222 is a volume within the design space that is defined by a corresponding prompt definition that specifies how objects appear and/or behave within the boundaries of the prompt volume 222. The prompt volume 222 exerts a “sphere of influence” (e.g., a volume of influence based on the boundaries) within the defined boundaries such that modifications made to the associated prompt definition causes changes to design objects within the boundaries. For example, the prompt definition enables the user to specify design intent text and/or non-textual inputs for objects that at least partially overlap the prompt volume 222. The prompt volume 222 a set of characteristics, including a spatial position (e.g., location and orientation), boundaries (defined via the textual definition or via user input within the prompt space 220), and shape (e.g., a sphere, a cuboid, a pyramid, an irregular 3D shape, etc.). In some embodiments, the prompt volume 222 includes weighted areas, weighted gradients, and/or linked prompt volumes (e.g., prompt volumes 222(1)-222(x)). In such instances, the linked prompted volumes include other overlapping prompt volumes and/or other prompt volumes linked in a hierarchy.

In various embodiments, when the user modifies the prompt volume 222, the prompt volume executes by updating one or more design objects 144, 270 that are within the sphere of influence of the prompt volume 222. For example, upon detecting a change to the prompt definition, the prompt volume 222 can receive a newly generated design object 270 and replace an existing design object 144 that is within the prompt volume 222. Upon executing the updates, the prompt volume 222 can cause the design exploration application 130 to generate a message indicating the change and “transmit” the message to other linked prompt volumes 222. In such instances, the prompt volumes 222 propagate changes among linked prompt volumes 222, which enables users to make modifications to multiple volumes within the design space 230 without applying global changes to the entire design space 230.

In various embodiments, the recommendation engine 252 generates a set of candidate actions 254 associated with the contents of a prompt volume 222. In some embodiments, the recommendation engine 252 receives a prompt volume 222 as an input and identifies object information associated with the design objects included in the prompt volume 222. The recommendation engine 252 generates a plurality of candidate actions 254 that are relevant to the design object. The recommendation engine 252 selects a subset of candidate actions 254 and transmits the subset of candidate actions 254 for the visualization module 250 to display. For example, the recommendation engine 252 can execute various optimization algorithms, generative artificial intelligence algorithms, and/or machine learning techniques to identify and/or generate a plurality of candidate actions 254 that the user can execute within the design space 230 that are associated with the one or more design objects. Additionally or alternatively, in some embodiments, the recommendation engine 252 computes a relevance score for each candidate action 254 that the recommendation engine 252 has generated in relation to the one or more design objects within the prompt volume 222. In such instances, the recommendation engine 252 can use the relevance scores to select the subset of candidate actions 254 to transmit to the visualization module 250.

In various embodiments, the intent manager 240 determines the intent of inputs provided by the user. For example, the intent manager 240 can comprise a natural language (NL) processor that parses text provided by the user. Additionally or alternatively, the intent manager 240 can process audio data to identify words included in audio data and parse the identified words. In various embodiments, the intent manager 240 identifies one or more keywords in textual data. In some embodiments, the intent manager 240 includes one or more keyword datasets 242 that the intent manager 240 references when identifying the one or more keywords included in textual data. For example, the keyword datasets 242 can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user).

The keywords can comprise particular words or phrases (e.g., demonstrative pronouns, technical terms, referential terms, etc.) that are relevant to designing 3D objects. For example, a user can input a regular sentence (“I want a hinge to connect here”) within an input area within the prompt space 220. The intent manager identifies “hinge,” “connect,” and “here” as words relevant to the ML model 180, 190 generating a design object 270. In such instances, the intent manager 240 can update the prompt space 220 by highlighting the keywords, enabling the user to provide additional details (e.g., non-textual data) for inclusion in the multimodal prompt 260.

In various embodiments, the visualization module 250 displays the design space 230 and/or the prompt space 220 via the GUI 120. In some embodiments, the visualization module 250 updates the prompt space 220 and/or the design space 230 based on inputs by the user and/or data received from the server device 160. For example, the visualization module 250 can initially respond to the user invoking a prompt via a hotkey or a marking menu within the prompt space by displaying an input area to receive data to include in the multimodal prompt 260. When the user initially inputs a textual phrase, the visualization module 250 can respond to the intent manager 240 identifying one or more keywords by updating the input area highlight the keywords and/or display contextual input areas proximate to at least one keyword. In this manner, the design exploration application 130 iteratively receives multiple modalities of input data to include into the multimodal prompt 260.

In various embodiments, the design exploration application 130 receives textual and/or non-textual data to include in the multimodal prompt via the input areas included in the prompt space. When providing non-textual data, the user can retrieve stored data, such as one or more stored data files 142 (e.g., stored geometries, stored CAD files, audio recordings, stored sketches, etc.) from the local data store 140. Additionally or alternatively, the user can retrieve contents from the design history 182 and can add the contents into the input area. In such instances, the contents from the design history 182 is stored in one or more data files 142 that the user retrieves from the local data store 140.

The multimodal prompt 260 is a prompt that includes two or more modalities of data (e.g., textual data, image data, audio data, etc.) that specifies the design intent of the user. In various embodiments, the design exploration application 130 receives multiple types of data and builds the multimodal prompt 260 to include each of the multiple types of data. For example, a user can initially write design intent text 262 that refers to a sketch. The design exploration application 130 then receives a sketch (e.g., a stored sketch or a sketch the user inputs into an input design area). Upon receiving the sketch, the design exploration application 130 can then generate the multimodal prompt 260 to include both the design intent text 262 and the sketch. In some embodiments, the multimodal prompt 260 can include multiple data inputs of the same modality. For example, the multimodal prompt 260 can include multiple design intent texts 262 (e.g., 262(1), 262(2), etc.) and/or multiple design files 264 (e.g., 264(1), 264(2), etc.).

The design intent text 262 includes textual data that describes the intent of the user. For example, the design intent text can include descriptions for characteristics of a target 3D design object (e.g., a handle made of titanium”). In some embodiments, the design exploration application 130 generates design intent text from a different type of data input. For example, the intent manager 240 can perform NL processing to identify words included in an audio recording. In such instances, the design exploration application 130 generates design intent text 262 that includes the identified words.

The design files 264 includes one or more files (e.g., CAD files, stored text, audio recordings, stored geometries, etc.) that the user adds to be included in the multimodal prompt 260. In some embodiments, the design files 264 can include textual data (e.g., textual descriptions, physical dimensions, etc.). In various embodiments, a user can add multiple design files 264 to include in the multimodal prompt 260. In some embodiments, the design exploration application 130 converts various types of data into the design files 264. For example, the user can record audio via the input area. In such instances, the design exploration application 130 can store audio recording as a design file 264. The design files 264 can include one or more modalities (e.g., textual data, video data, audio data, image data, etc.).

In some embodiments, the design space references 266 can include one or more references to the prompt space 220 and/or the design space 230. For example, the user can input text that references a specific application state (e.g., “make the thing selected by the current tool lighter,” “generate a seat for the car in this view,” etc.). In such instances, the design exploration application 130 determines the application state the user is referencing. The design exploration application 130 can then include the reference in the multimodal prompt 260 as the design space reference 266.

In various embodiments, the intent management application 170 receives and processes the multimodal prompt 260 to identify the modalities of the contents of the multimodal prompt 260. For example, the intent management application 170 the modalities of the design intent text 262, the one or more design files 264, and/or the one or more design space references 266 included in the multimodal prompt 260. For example, the intent management application 170 can identify a combination of text, image, and video modalities included in the multimodal prompt. The intent management application 170 identifies at least one ML model 180, 190 that was trained with that combination of modalities and selects one of the identified ML models 180, 190. The intent management application 170 executes the selected ML model by inputting the multimodal prompt 260 into the selected ML model. The selected ML model generates a design object 270 in response to the multimodal prompt 260. In some embodiments, the server device includes the generated design object 270 in the design history 182. In such instances, the generated design object 270 is a portion of the design history 182 used as training data to train one or more trained ML models 180 (e.g., further training the selected ML model, training other ML models, etc.).

### Contextual Recommendations for Three-Dimensional Design Spaces

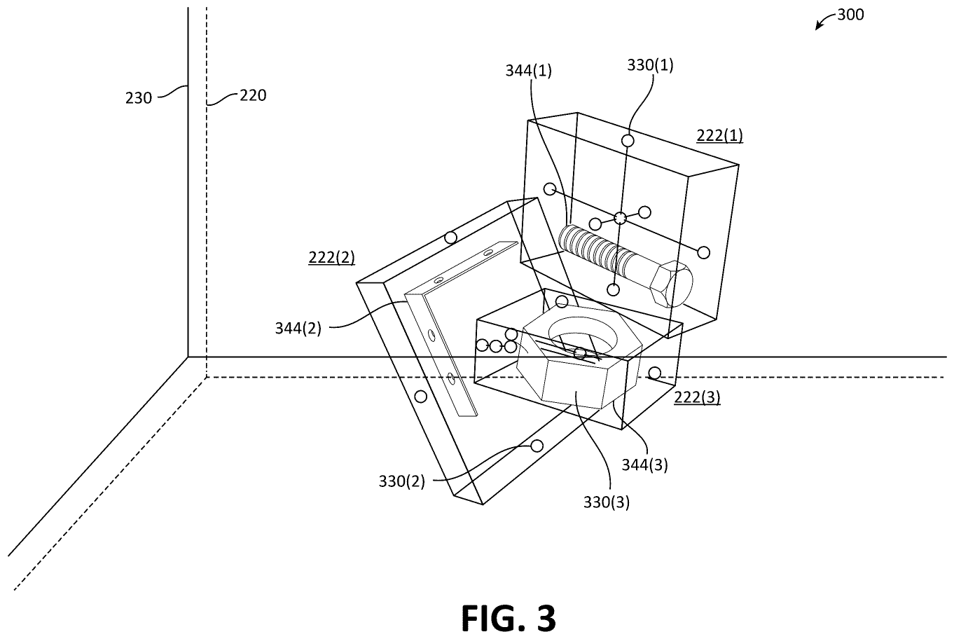

FIG. 3 is an exemplar illustration of the design space 230 and the prompt space 220 of FIG. 2, according to various embodiments. As shown, the visualization 300 includes, without limitation, the prompt space 220, the design space 230, a plurality of prompt volumes 222 (e.g., 222(1), 222(2), etc.), a plurality of prompt volume boundaries 330 (e.g., 330(1), 330(2), etc.), and a plurality of geometries 344 (e.g., 344(1), 344(2)) of a plurality of design objects 144.

In various embodiments, the visualization module 250 of the design exploration application 130 displays a visualization 300 of the design space 230 and the prompt space 220 via the GUI 120. As shown, the visualization displays a unified prompt space, where the prompt space 220 is overlayed over the design space 230. In such instances, the user can invoke a prompt anywhere within the design space 230.

The design space 230 is a volume that displays one or more geometries 344 of design objects 144 that are part of a 3D design. The design space 230 can include two-dimensional (e.g., panels, textures, overlays, etc.) and/or three-dimensional content. In various embodiments, the design exploration application 130 enables the user to manipulate a camera within the design space 230 using one or more tools (not shown) to control the roll, pitch, yaw, zoom level, etc., of the camera. Additionally or alternatively, the design exploration application 130 includes controls to sketch images, create new geometries 344 and textures and/or edit existing geometries 344 of design objects 144. In various embodiments, the design space 230 can include multiple geometries 344 that combine to form an overall 3D design. For example, the plurality of geometries 344(1)-344(3) can be included in an overall 3D design.

The prompt space 220 is a volume that overlays at least a portion of the design space 230. In various embodiments, the user can invoke a prompt (e.g., a prompt volume 222 or a prompt input area) via a hotkey or a marketing menu within the prompt space 220. For example, the user can select a tool (not shown) to draw one or more of the prompt volumes 222. Additionally or alternatively, in some embodiments, the user can press a hotkey to invoke the one or more of the prompt volumes 222. In some embodiments, the prompt space can include a prompt input area where the user can add textual data to specify portions of a prompt definition for the corresponding prompt volume 222.

The prompt volume boundaries 330 define the volume within the design space 230. The prompt definition specifies how objects appear and/or behave within the particular prompt volume boundaries 330. Additionally or alternatively, prompt definition defines the characteristics of the sphere of influence within the prompt volume boundaries 330. In various embodiments, the prompt volumes 222 operate and execute such that modifications made to the associated prompt definition causes changes to the geometries 344 within the prompt volume boundaries 330. For example, the prompt definition can define characteristics for one or more objects (e.g., a screw) within the prompt volume boundary 330(1). The prompt volume 222 operates by causing the trained ML model 180 to generate a design object 270 having a geometry 344(1). In such instances, changes to the prompt definition causes the prompt volume 222 to update the object, causing the trained ML model 180 to generate a new design object 270 having a new geometry (not shown) to replace the geometry 344(1).

In some embodiments, the prompt volume boundaries 330 have coordinates that define the spatial position (e.g., location and orientation), and shape (e.g., a sphere, a cuboid, a pyramid, an irregular 3D shape, etc.) of the prompt volume 222. In some embodiments, the prompt volume 222 includes weighted areas and weighted gradients in portions of the prompt volume 222. For example, the prompt volume boundary 330(2) can include one or more weighted values and/or gradients that emphasize one group of characteristics (e.g., lighter materials, less density, etc.) closer to the middle of the prompt boundaries 330(2) and emphasize a different group of characteristics (e.g., cheaper materials, higher strength, etc.) closers to the edges of the prompt volume boundaries 330(3).

In various embodiments, a single prompt volume 222 can be linked to one or more other prompt volumes, where the linked prompt volumes are within the sphere of influence of the single prompt volume 222. The linked prompt volumes include other overlapping prompt volumes and/or other prompt volumes linked in a hierarchy. In such instances, updates to the prompt volume 222 cause the prompt volume to propagate changes by transmitting messages indicating the changes to the linked prompt volumes 222. The linked prompt volumes respond by performing updates based on the indication and transmitting messages indicating the updates to other prompt volumes that are within the sphere of influence of the linked prompt volumes 222. In this manner, a user can apply changes to a plurality of prompt volumes 222 by modifying a single prompt definition.

For example, the prompt volume 222(2) overlaps with the prompt volumes 222(1) and 222(3). The prompt volumes 222(1) and 222(3) are thus within the sphere of influence of the prompt volume 222(2). When the user modifies the prompt definition for the prompt volume 222(2), the prompt volume operates by updating the design objects 144 (e.g., the design object 144(2)) that has the geometry 344(2) within the sphere of influence of the prompt volume 222(2). The prompt volume 222 can receive a newly generated design object 270 having a new geometry (not shown) and replace the existing geometry 344(2) with the newly generated design object 270. Upon executing the updates, the prompt volume 222(2) can cause the design exploration application 130 to generate a message indicating the change and “transmit” the message to other linked prompt volumes 222(1), 222(3). In some embodiments, the prompt volumes 222 operate on an execution cycle. In such instances, a given prompt volume 222 receives a message indicating a change during one cycle and propagates the message during a subsequent cycle.

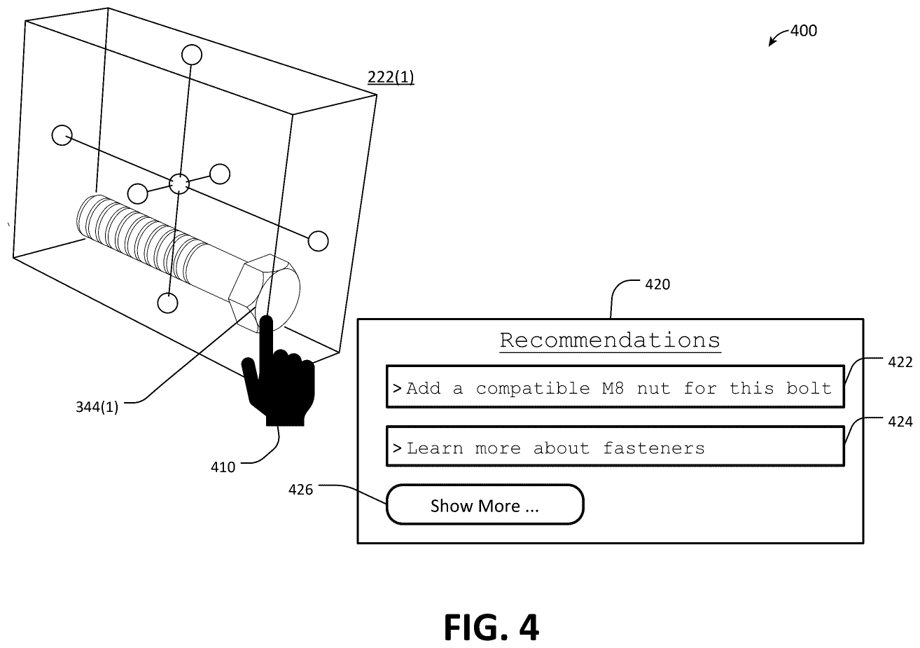

FIG. 4 is an exemplar illustration of a recommendation window based on contents of the prompt volume of FIG. 2, according to various embodiments. As shown, the visualization 400 includes a prompt volume 222(1) including a design object 344(1), a cursor 410, and a recommendation window 420 including a set of selectable options 422-426.

In operation, the recommendation engine 252 determines that the recommendation window 420 is to be shown within the design space 230. The recommendation engine 252 receives the prompt volume 222(1) as an input and identifies the design object 344(1). The recommendation engine 252 generates a plurality of candidate actions 254 associated with the design object 344(1) and selects a subset of candidate actions 254 that are of particular relevance to the design object 344(1). The recommendation engine 252 transmits the subset of candidate actions 254 to the visualization module 250, where the visualization module 250 generates the recommendation window 420 containing selectable options 422-426. The selectable options 422-424 trigger the design exploration application 130 to execute the corresponding candidate actions 254. The selectable option 426 enables the user to invoke the design exploration application 130 to display additional candidate actions 254 as selectable options.

In various embodiments, the recommendation engine 252 detects an input associated with displaying the recommendation window 420. For example, the user can provide a user input (e.g., the cursor 410 hovering over the design object 344(1), right clicking when the cursor 410 is proximate to the prompt volume 222(1), etc.) invoking a request for a recommendation associated with a specific design object (e.g., the design object 344(1)) and/or a specific prompt volume 222 (e.g., the prompt volume 222(1)). In another example, the recommendation engine 252 can detect a cursor hovering over a portion of a prompt volume 222 for a specified period and determine that the user invoked a requires for a recommendation associated with the contents of the prompt volume 222. Additionally or alternatively, the recommendation engine 252 can include scripts or code that is triggered and executed based on when changes occur within the sphere of influence of the prompt volume 222, and/or when the recommendation engine 252 computes new recommendations based on selections and/or user inputs.

In various embodiments, the recommendation engine 252 receives the prompt volume 222(1) as an input and processes the prompt volume 222(1) to infer and/or identify one or more design objects 344 (e.g., the design object 344(1)) included in the prompt volume 222(1). Upon identifying the design object 344(1), the recommendation engine 252 can generate and/or retrieve object information associated with the design object 344(1). For example, the object information for the design object 344(1) can include identification information that indicates the specific type of object (e.g., a bolt), object attribute information, including shape and material, and/or complementary objects (e.g., a fastener for a bolt).

In some embodiments, the recommendation engine 252 can receive other information as inputs. For example, the recommendation engine 252 can receive the overall design as an input and can identify the one or more design objects 344 within the prompt volume 222(1) based in part on the overall design. Additionally or alternatively, the recommendation engine 252 can receive outputs from the intent manager 240. In such instances, the recommendation engine 252 can use various algorithms to refine the identification of the one or more design objects 344 based in part on the output of the intent manager 240.

In various embodiments, the recommendation engine 252 can identify various actions a user can take that are associated with the one or more design objects 344 included in the prompt volume 222. For example, the recommendation engine 252 can execute various optimization algorithms, generative artificial intelligence algorithms, and/or machine learning techniques to identify and/or generate a plurality of candidate actions 254 that the user can execute that are associated with the design objects 344(1). For example, the recommendation engine 252 can generate candidate actions 254 for substituting the design object 344(1) with an alternative design object (e.g., substituting the bolt with a screw or a nail), generating an additional design object (e.g., a fastener) to complement the design object 344(1), and/or changing an attribute of the first design object (e.g., changing a material, shape, etc.). In some embodiments, the recommendation engine 252 generates a candidate action 254 associated with accessing information associated with the design object 344 from an external data source. For example, the recommendation engine 252 can identify information associated with the design object 344(1) (e.g., reference material about the functionality of the object type) and can generate a candidate action 254 associated with the user accessing the information from the external data source.

Additionally or alternatively, the recommendation engine 252 can generate a candidate action 254 for transmitting a prompt associated with the design object 344(1). In such instances, the recommendation engine 252 can retrieve one or more previously-generated prompts from the local data store 140 and can provide the retrieved prompt and/or generate new prompts based on the retrieved prompt, where the new prompt is associated with generating an updated design object associated with the design object 344 (e.g., generating an alternative design object and/or a complementary design object).

In various embodiments, the recommendation engine 252 computes a relevance score for each candidate action 254 that the recommendation engine 252 has generated in relation to the one or more design objects 344 within the prompt volume 222(1). In various embodiments, the relevance score is based on historical data, such as previous actions performed by the user and/or a group of users, previous recommendations selected by the user, and so forth. The relevance score indicates whether the candidate action 254 may be of particular interest for use in furthering the progress of the user in completing a design using the design object 344. For example, the recommendation engine 252 can compute relevance scores based on statistical analysis of the historical data (e.g., using variances, mean values, etc.).

Additionally or alternatively, in some embodiments, the recommendation engine 252 applies weight values to the relevance scores to generate weighted relevance scores. For example, the recommendation engine 252 can determine weight values for each of the one or more design objects 344(1), 544(1) within the prompt volume 222(1). In such instances, the recommendation engine 252 can apply the weight value for the design object 344(1) to each candidate action 254 that is associated with the design object 344(1) and apply the weight value for the design object 544(1) to each candidate action 254 that is associated with the design object 544(1).

In various embodiments, the recommendation engine 252 selects a set of one or more candidate actions 254 based on the relevance scores (or weighted relevance scores) the recommendation engine 252 generated for each of the candidate actions 254. In various embodiments, the design exploration application 130 can select a specific number of candidate actions 254 (e.g., select the three candidate actions 254 with the highest relevance scores). Alternatively, the recommendation engine 252 can select each candidate action 254 that exceeds a threshold value.

In various embodiments, the visualization module 250 of the design exploration application 130 generates the recommendation window 420 within the design space 230. In some embodiments, the visualization module 250 attaches the recommendation window 420 to a portion (e.g., an edge, surface, volume, etc.) of a geometry of a design object 344 within the prompt volume 222(1). In such instances, the visualization module 250 can move the recommendation window 420 to new locations in response to the user modifying (e.g., moving, scaling, etc.) the design object 344. Alternatively, in some embodiments, the visualization module 250 attaches the recommendation window 420 to an anchor within the design space 230. In such instances, the recommendation window 420 remains in the same location independent of modifications to the design object 344. In such instances, the recommendation window 420 can remain at the same location until the user manually moves the recommendation window 420 to a new location. In various embodiments, the visualization module 250 adds one or more selectable options 422-424 for the set of candidate actions 254 within the recommendation window 420. In various embodiments, the visualization module 250 updates the recommendation window 420 to generate an updated recommendation window containing different selectable options.

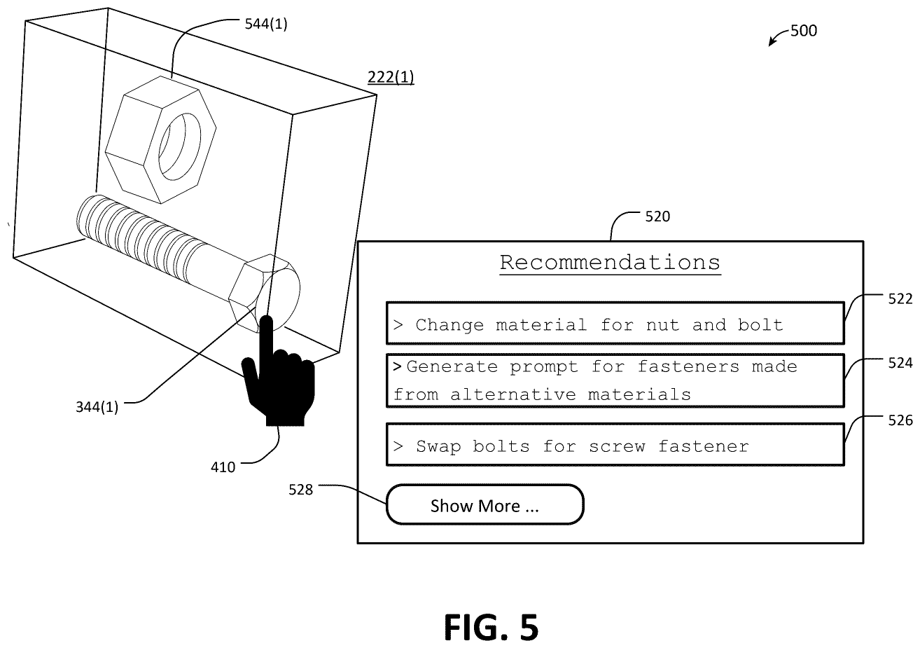

FIG. 5 is an exemplar illustration of an updated recommendation window based on updated contents of the prompt volume of FIG. 2, according to various embodiments. As shown, the visualization 500 includes the prompt volume 222(1) including the design object 344(1), an additional design object 544(1), the cursor 410, and an updated recommendation window 520 including a set of selectable options 522-528.

In operation, the recommendation engine 252 generates updated recommendations based on updates to the prompt volume 222(1) (e.g., the user adding the design object 544(1)). In such instances, the recommendation engine 252 can generate a new set of candidate actions 254 and can cause the visualization module 250 to generate the updated recommendation window 520 containing selectable options 522-526 for the updated set of candidate actions 254.

In some embodiments, the recommendation engine 252 detects changes to the prompt volume 222(1) and updates the plurality of candidate actions 254 in parallel. Alternatively, in some embodiments, the recommendation engine 252 waits for a trigger (e.g., a user input, an expiration of update period triggered after the update, etc.) before updating the plurality of candidate action 254. For example, the recommendation engine 252 can wait for 20 seconds after a change to the prompt volume 222(1) before updating the plurality of candidate actions 254 and generating the updated recommendation window 520. In some embodiments, the user performs an action to invoke an update to the plurality of candidate actions 254. For example, the user can select a selectable option (not shown) to receive different recommendations. In such instances, the recommendation engine 252 can respond to the user selection by modifying the relevance scores for the plurality of candidate actions 254, such as by lowering the relevance scores of the candidate actions 254 that had corresponding selectable options 422-424 included in the recommendation window 420. The recommendation engine 252 can then select a different set of candidate actions 254 to transmit to the visualization module 250 based on the updated relevance scores. In some embodiments, the recommendation engine 252 can determine weight values for each of the additional design objects 544(1). In such instances, the recommendation engine 252 can apply the weight value for the respective design objects 344(1), 544(1) to the relevance scores of one or more candidate action 254. For example, the recommendation engine 252 applies the weight value for 344(1) to the relevance score for each candidate action 254 that is associated with the design object 344(1) and apply the weight value for the design object 544(1) to the relevance score for each candidate action 254 that is associated with the design object 544(1).

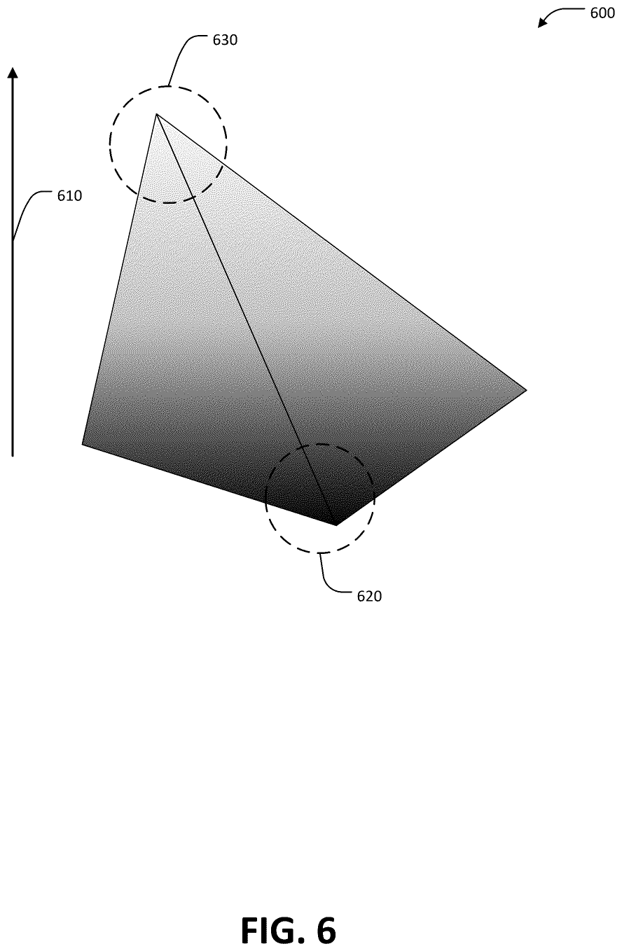

FIG. 6 is an exemplar illustration of a weighted prompt volume 600, according to various embodiments. As shown, the weighted prompt volume 600 includes, without limitation, a first weighted portion 620 and a second weighted portion 630. In various embodiments, the weighted prompt volume 600 has a configurable sphere of interest. For example, the weighted prompt volume 600 can adhere to a weighted gradient 610 that emphasizes a characteristic (e.g., density) closer to the middle based the weighted prompt volume 600. As a result, the plurality of candidate actions 254 for the weighted prompt volume 600 are weighted. The recommendation engine 252 generates weighted relevance scores by applying greater weights to candidate actions 254 associated with the first weighted portion 620 and applying lower weights to candidate actions associated with the second weighted portion 630. In this manner, the sphere of influence for the weighted prompt volume 600 to for candidate actions associated with a particular portion of the weighted prompt volume 600 gradually trails off along the weighted gradient 610.

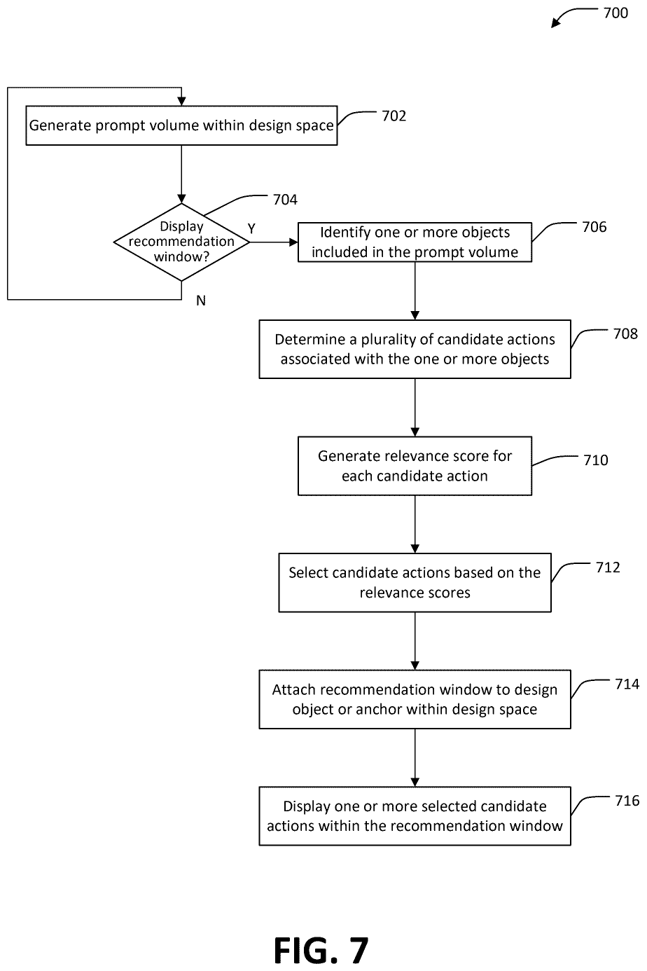

FIG. 7 sets forth a flow diagram of method steps for generating recommendations within a design space, according to various embodiments. Although the method steps are described with reference to the systems of FIGS. 1-6, persons skilled in the art will understand that any system configured to implement the method steps, in any order, falls within the scope of the embodiments.

As shown, a method 700 begins at step 702, where the design exploration application 130 generates a prompt volume 222 within the design space 230. In various embodiments, the design exploration application 130 can display a unified prompt space for a user to generate a prompt that includes a prompt definition and prompt volume 222. In such instances, the prompt space 220 overlaps the design space 230 and a user can invoke a prompt anywhere in the design space. The design exploration application responds to a user input by generating a prompt, including a prompt volume 222 within the design space 230 that adheres to an appearance and behavior specified by a corresponding prompt definition. The prompt definition enables a user to specify design intent text and/or non-textual inputs. The prompt volume 222 has a spatial position and a set of prompt volume boundaries 330 that are defined via the textual definition, or via user input within the design space 230. The prompt volume 222 includes a set of characteristics, including shape (e.g., spheres, cuboids, pyramids, irregular 3D shapes, etc.), weighted portions 620, 630, weighted gradients 610, and/or linked prompt volumes. The prompt volume 222 exerts a sphere of influence within the defined prompt volume boundaries 330 such that modifications made to the associated prompt definition causes changes to design objects within the boundaries.

At step 704, the design exploration application 130 determines whether to display a recommendation window 420. In various embodiments, a recommendation engine 252 included in the design exploration application 130 detects an input associated with displaying the recommendation window 420. For example, the user can provide a user input invoking a request for a recommendation associated with a specific design object (e.g., the design object 344(1)) and/or a specific prompt volume 222 (e.g., the prompt volume 222(1)). In another example, the recommendation engine 252 can detect a cursor hovering over a portion of a prompt volume 222 for a specified period and determine that the user invoked a requires for a recommendation associated with the contents of the prompt volume 222. Additionally or alternatively, the recommendation engine 252 can include scripts or code that is triggered and executed based on when changes occur within the sphere of influence of the prompt volume 222, and/or when the recommendation engine 252 computes new recommendations based on selections and/or user inputs. When the recommendation engine 252 determines to display the recommendation window 420, the design exploration application 130 proceeds to step 706. Otherwise, the recommendation engine 252 determines not to display the recommendation window 420 and the design exploration application 130 returns to step 702.

At step 706, the design exploration application 130 identifies one or more objects included in the prompt volume 222. In various embodiments, the recommendation engine 252 receives the prompt volume 222(1) as an input and processes the prompt volume 222(1) to infer and/or identify one or more design objects 344 included in the prompt volume 222(1). Upon identifying the one or more design objects 344, the recommendation engine 252 can generate and/or retrieve object information associated with each design object 344. For example, the object information can include identification information that indicates the specific type of object, object attribute information, including shape, material, and/or complementary objects (e.g., a fastener for a bolt). In some embodiments, the recommendation engine 252 can receive other information as inputs. For example, the recommendation engine 252 can receive the overall design as an input and can identify the one or more design objects 344 within the prompt volume 222(1) based in part on the overall design. Additionally or alternatively, the recommendation engine 252 can receive outputs from the intent manager 240. In such instances, the recommendation engine 252 can use various algorithms to refine the identification of the one or more design objects 344 based in part on the output of the intent manager 240.

At step 708, the design exploration application 130 determines a plurality of candidate actions 254 associated with the one or more objects. In various embodiments, the recommendation engine 252 can identify various actions a user can take that are associated with the one or more design objects 344 included in the prompt volume 222. For example, the recommendation engine 252 can execute various optimization algorithms, generative artificial intelligence algorithms, and/or machine learning techniques to identify and/or generate a plurality of candidate actions 254 that the user can execute within the design space 230 that are associated with the one or more design objects 344. For example, the recommendation engine 252 can generate candidate actions 254 for substituting a design object 344(1) with an alternative design object, generating an additional design object (e.g., the design object 544(1)) to complement the design object 344(1), and/or changing an attribute of the first design object (e.g., changing a material, shape, etc.). In some embodiments, the recommendation engine 252 generates a candidate action 254 associated with accessing information associated with the design object 344 from an external data source. For example, the recommendation engine 252 can identify information associated with the design object 344 (e.g., reference material about the functionality of the object type) and can generate a candidate action 254 associated with the user accessing the information from the external data source.

Additionally or alternatively, the recommendation engine 252 can generate a candidate action 254 for transmitting a prompt associated with the design object 344. In such instances, the recommendation engine 252 can retrieve one or more previously-generated prompts from the local data store 140 and can provide the retrieved prompt and/or generate new prompts based on the retrieved prompt, where the new prompt is associated with generating an updated design object associated with the design object 344 (e.g., generating an alternative design object and/or a complementary design object).

At step 710, the design exploration application 130 generates a relevance score for each candidate action 254. In various embodiments, the recommendation engine 252 computes a relevance score for each candidate action 254 that the recommendation engine 252 has generated in relation to the one or more design objects 344 within the prompt volume 222(1). In various embodiments, the relevance score is based on historical data, such as previous actions performed by the user and/or a group of users, previous recommendations selected by the user, and so forth. The relevance score indicates whether the candidate action 254 may be of particular interest for use in furthering the progress of the user in completing a design using the design object 344. For example, the recommendation engine 252 can compute relevance scores based on statistical analysis of the historical data (e.g., using variances, mean values, etc.).

Additionally or alternatively, in some embodiments, the recommendation engine 252 applies weight values to the relevance scores to generate weighted relevance scores. For example, the recommendation engine 252 can determine weight values for each of the one or more design objects 344(1), 544(1) within the prompt volume 222(1). In such instances, the recommendation engine 252 can apply the weight value for the design object 344(1) to each candidate action 254 that is associated with the design object 344(1) and apply the weight value for the design object 544(1) to each candidate action 254 that is associated with the design object 544(1).

At step 712, the design exploration application 130 selects candidate actions 254 based on the relevance scores. In various embodiments, the recommendation engine 252 selects a set of one or more candidate actions 254 based on the relevance scores (or weighted relevance scores) the recommendation engine 252 generated for each of the candidate actions 254. In various embodiments, the design exploration application 130 can select a specific number of candidate actions 254 (e.g., select the three candidate actions 254 with the highest relevance scores). Alternatively, the recommendation engine 252 can select each candidate action 254 that exceeds a threshold value.

At step 714, the design exploration application 130 attaches the recommendation window 420 to a design object or an anchor within the design space 230. In various embodiments, the visualization module 250 of the design exploration application 130 generates the recommendation window 420 within the design space 230. In some embodiments, the visualization module 250 attaches the recommendation window 420 to a portion (e.g., an edge, surface, volume, etc.) of a geometry of a design object 344 within the prompt volume 222(1). In such instances, the visualization module 250 can move the recommendation window 420 to new locations in response to the user modifying (e.g., moving, scaling, etc.) the design object 344. Alternatively, in some embodiments, the visualization module 250 attaches the recommendation window 420 to an anchor within the design space 230. In such instances, the recommendation window 420 remains in the same location independent of modifications to the design object 344. In such instances, the recommendation window 420 can remain at the same location until the user manually moves the recommendation window 420 to a new location.

At step 716, the design exploration application 130 displays one or more selected candidate actions 254 within the recommendation window 420. In various embodiments, the visualization module 250 adds one or more selectable options 422-424 for the set of candidate actions 254 within the recommendation window 420. In various embodiments, the visualization module 250 updates the recommendation window 420 to generate an updated recommendation window 520 containing different selectable options 522-526. In some embodiments, the recommendation engine 252 generates updated recommendations in parallel with updates to the prompt volume 222(1) (e.g., the user adding the design object 544(1)). In such instances, the recommendation engine 252 can generate a new set of recommendations and can cause the visualization module 250 to generate an updated recommendation window 520 containing selectable options 522-526 for the updated set of candidate actions 254.

### System Implementation

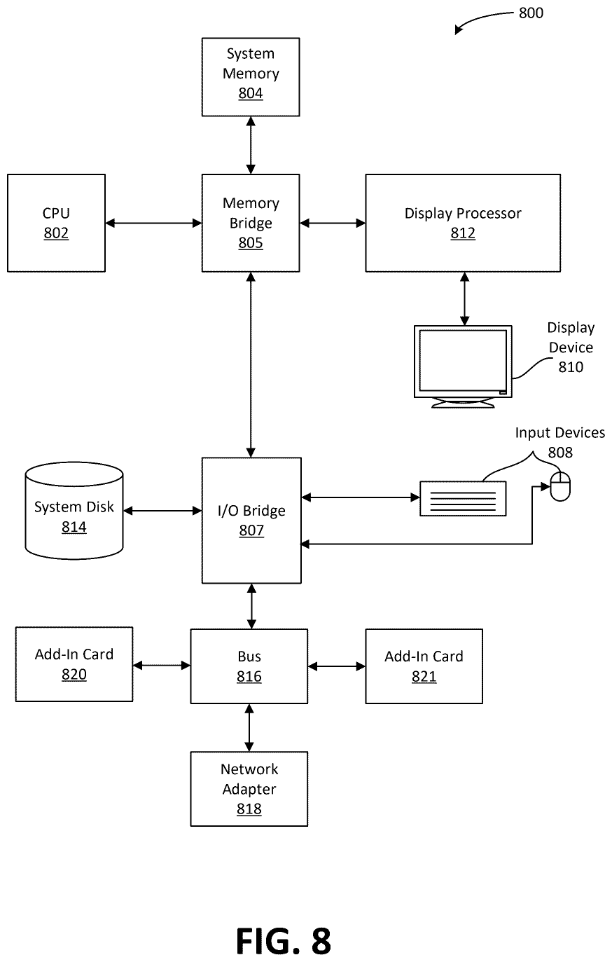

FIG. 8 depicts one architecture of a system within which embodiments of the present disclosure may be implemented. This figure in no way limits or is intended to limit the scope of the present disclosure. In various implementations, system 800 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 800 may be coupled together to practice one or more aspects of the present disclosure.

As shown, system 800 includes a central processing unit (CPU) 802 and a system memory 804 communicating via a bus path that may include a memory bridge 805. CPU 802 includes one or more processing cores, and, in operation, CPU 802 is the master processor of system 800, controlling and coordinating operations of other system components. System memory 804 stores software applications and data for use by CPU 802. CPU 802 runs software applications and optionally an operating system. Memory bridge 805, which may be, e.g., a Northbridge chip, is connected via a bus or other communication path (e.g., a HyperTransport link) to an I/O (input/output) bridge 807. I/O bridge 807, which may be, e.g., a Southbridge chip, receives user input from one or more user input devices 808 (e.g., keyboard, mouse, joystick, digitizer tablets, touch pads, touch screens, still or video cameras, motion sensors, and/or microphones) and forwards the input to CPU 802 via memory bridge 805.

A display processor 812 is coupled to memory bridge 805 via a bus or other communication path (e.g., a PCI Express, Accelerated Graphics Port, or HyperTransport link); in one embodiment display processor 812 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 804.

Display processor 812 periodically delivers pixels to a display device 810 (e.g., a screen or conventional CRT, plasma, OLED, SED or LCD based monitor or television). Additionally, display processor 812 may output pixels to film recorders adapted to reproduce computer generated images on photographic film. Display processor 812 can provide display device 810 with an analog or digital signal. In various embodiments, one or more of the various graphical user interfaces set forth in Appendices A-J, attached hereto, are displayed to one or more users via display device 810, and the one or more users can input data into and receive visual output from those various graphical user interfaces.

A system disk 814 is also connected to I/O bridge 807 and may be configured to store content and applications and data for use by CPU 802 and display processor 812. System disk 814 provides non-volatile storage for applications and data and may include fixed or removable hard disk drives, flash memory devices, and CD-ROM, DVD-ROM, Blu-ray, HD-DVD, or other magnetic, optical, or solid-state storage devices.

A switch 816 provides connections between I/O bridge 807 and other components such as a network adapter 818 and various add-in cards 820 and 821. Network adapter 818 allows system 800 to communicate with other systems via an electronic communications network, and may include wired or wireless communication over local area networks and wide area networks such as the Internet.

Other components (not shown), including USB or other port connections, film recording devices, and the like, may also be connected to I/O bridge 807. For example, an audio processor may be used to generate analog or digital audio output from instructions and/or data provided by CPU 802, system memory 804, or system disk 814. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 812 incorporates circuitry optimized for graphics and video processing, including, for example, video output circuitry, and constitutes a graphics processing unit (GPU). In another embodiment, display processor 812 incorporates circuitry optimized for general purpose processing. In yet another embodiment, display processor 812 may be integrated with one or more other system elements, such as the memory bridge 805, CPU 802, and I/O bridge 807 to form a system on chip (SoC). In still further embodiments, display processor 812 is omitted and software executed by CPU 802 performs the functions of display processor 812.

Pixel data can be provided to display processor 812 directly from CPU 802. In some embodiments of the present disclosure, instructions and/or data representing a scene are provided to a render farm or a set of server computers, each similar to system 800, via network adapter 818 or system disk 814. The render farm generates one or more rendered images of the scene using the provided instructions and/or data. These rendered images may be stored on computer-readable media in a digital format and optionally returned to system 800 for display. Similarly, stereo image pairs processed by display processor 812 may be output to other systems for display, stored in system disk 814, or stored on computer-readable media in a digital format.

Alternatively, CPU 802 provides display processor 812 with data and/or instructions defining the desired output images, from which display processor 812 generates the pixel data of one or more output images, including characterizing and/or adjusting the offset between stereo image pairs. The data and/or instructions defining the desired output images can be stored in system memory 804 or graphics memory within display processor 812. In an embodiment, display processor 812 includes 3D rendering capabilities for generating pixel data for output images from instructions and data defining the geometry, lighting shading, texturing, motion, and/or camera parameters for a scene. Display processor 812 can further include one or more programmable execution units capable of executing shader programs, tone mapping programs, and the like.

Further, in other embodiments, CPU 802 or display processor 812 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 802, display processor 812, or one or more other processing devices or any combination of these different processors.

CPU 802, render farm, and/or display processor 812 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 800 may be a robot or robotic device and may include CPU 802 and/or other processing units or devices and system memory 804. In such embodiments, system 800 may or may not include other elements shown in FIG. 1. System memory 804 and/or other memory units or devices in system 800 may include instructions that, when executed, cause the robot or robotic device represented by system 800 to perform one or more operations, steps, tasks, or the like.

In sum, the disclosed techniques can be used to generate designs for one or more 3D objects based on actions performed by users via a GUI. In various embodiments, a design exploration application displays a prompt space for a user to generate a prompt. The prompt space overlaps the design space, where a user can invoke a prompt anywhere in the design space. The design exploration application responds to a user input in the prompt space by generating a prompt that includes a prompt volume. The prompt volume has a spatial position and boundaries that are defined via the textual definition, or via user input within the prompt space. The prompt volume includes a set of characteristics, including shape (e.g., spheres, cuboids, pyramids, irregular 3D shapes, etc.), weighted areas, and weighted gradients. The prompt volume exerts a sphere of influence within the defined boundaries such that selections and/or modifications made to the design objects within the sphere of influence change the responses made by the design exploration application.

When the user invokes a request for a recommendation within a prompt volume, a recommendation engine within the design exploration application receives information associated with the prompt volume as an input. In some embodiments, the recommendation engine receives intent information from associated with the prompt volume and/or the corresponding prompt definition from an intent manager. Additionally or alternatively, the recommendation engine receives the prompt volume and/or the overall design as direct inputs. The recommendation engine processes the prompt volume to identify one or more design objects within the prompt volume. The recommendation engine searches one or more data sources for information associated with the one or more identified objects. The data sources include previous prompts sent to a ML model, similar or alternative design geometries, geometry attributes, and external information. The recommendation engine generates a plurality of actions based on the retrieved information and generates relevance scores for each of the candidate actions. The recommendation engine selects a set of candidate actions to display. The design exploration application generates a recommendation window within the design space, where the recommendation window includes the set of candidate actions as selectable options for the user to perform. Based on a selection of a candidate action, the recommendation engine modifies the relevance score for the candidate action that the user selected.

At least one technical advantage of the disclosed techniques relative to the prior art is that the disclosed techniques can be used to identify specific objects within a design space and generate contextually-relevant recommendations associated with the identified objects. Thus, the design recommendation generated using the disclosed techniques are typically more specific and useful to a user and, accordingly, are more likely to be selected by the user, relative to the design recommendations generated using prior art techniques. In this regard, the disclosed techniques enable users to define spatial volumes within a design space that constrain the scope of the 3D objects. A design exploration application using such spatial volumes can identify the relevant portion of an overall design with greater precision and can generate recommendations that are more relevant to a particular 3D object or portion of an overall design. Further, by enabling a user to request recommendations for specific portions of an overall design, the user can complete specific portions of an overall design faster, reducing the overall design time for the user and increasing overall design quality relative to what can be achieved using prior art techniques. These technical advantages provide one or more technological advancements over prior art approaches.

1. In various embodiments, a computer-implemented method for generating recommendations for a generative design comprises receiving a selection of a prompt volume within a design space, where the design space is generated by a design exploration application, and the prompt volume defines a sphere of influence within the prompt volume, identifying one or more design objects within the prompt volume, generating a plurality of candidate actions associated with the one or more design objects, and displaying, within a recommendation window included in the design space, at least one candidate action from the plurality of candidate actions.

2. The computer-implemented method of clause 1, further comprising, for each candidate action included in the plurality of candidate actions, generating a relevance score to generate a plurality of relevance scores.

3. The computer-implemented method of clause 1 or 2, further comprising determining, for each design object included in the one or more design objects, a weight to generate a set of weights, and applying, for each relevance score included in the plurality of relevance scores, at least one weight in the set of weights to generate a plurality of weighted relevance scores.

4. The computer-implemented method of any of clauses 1-3, further comprising determining a weight for a portion of the sphere of influence, and applying, for at least one relevance score included in the plurality of relevance scores, the weight to generate a weighted relevance score.

5. The computer-implemented method of any of clauses 1-4, further comprising determining an update to the prompt volume, updating, based on the update to the prompt volume, the relevance scores for the plurality of candidate actions to generate a plurality of updated relevance scores, selecting an updated set of candidate actions based on the updated relevance scores, and modifying the recommendation window to display at least one candidate action from the updated set of candidate actions.

6. The computer-implemented method of any of clauses 1-5, further comprising detecting a user input indicating a request to update the at least one candidate action from the plurality of candidate actions, in response to the user input, updating the relevance scores for the plurality of candidate actions, selecting an updated set of candidate actions based on the updated relevance scores, and modifying the recommendation window to display at least one candidate action from the updated set of candidate actions.

7. The computer-implemented method of any of clauses 1-6, where generating a plurality of candidate actions comprises retrieving, from a local data source, a prompt associated with the one or more design objects, generating a candidate action for transmitting the prompt to a trained machine learning (ML) model to generate an updated design object based on the prompt, where the candidate action is included in the plurality of candidate actions.

8. The computer-implemented method of any of clauses 1-7, where the plurality of candidate actions includes at least one of substituting a first design object of the one or more design objects with an alternative design object, generating an additional design object to complement the first design object, changing an attribute of the first design object, transmitting a prompt associated with the first design object, or accessing information associated with the first design object from an external data source.

9. The computer-implemented method of any of clauses 1-8, further comprising attaching the recommendation window to a first design object included in the one or more design objects, detecting that the first design object has moved, and in response, moving the recommendation window to a new location within the design space.

10. The computer-implemented method of any of clauses 1-9, further comprising attaching the recommendation window to an anchor location within the design space.

11. In various embodiments, one or more non-transitory computer-readable media include instructions that, when executed by one or more processors, cause the one or more processors to generate design content by performing the steps of receiving a selection of a prompt volume within a design space, where the design space is generated by a design exploration application, and the prompt volume defines a sphere of influence within the prompt volume, identifying one or more design objects within the prompt volume, generating a plurality of candidate actions associated with the one or more design objects, and displaying, within a recommendation window included in the design space, at least one candidate action from the plurality of candidate actions.

12. The one or more non-transitory computer-readable media of clause 11, further comprising instructions that, when executed by the one or more processors, cause the one or more processors to perform the step of, for each candidate action included in the plurality of candidate actions, generating a relevance score to generate a plurality of relevance scores.

13. The one or more non-transitory computer-readable media of clause 11 or 12, further comprising instructions that, when executed by the one or more processors, cause the one or more processors to perform the steps of determining, for each design object included in the one or more design objects, a weight to generate a set of weights, and applying, for each relevance score included in the plurality of relevance scores, at least one weight in the set of weights to generate a plurality of weighted relevance scores.

14. The one or more non-transitory computer-readable media of any of clauses 11-13, further comprising instructions that, when executed by the one or more processors, cause the one or more processors to perform the steps of determining a weight for a portion of the sphere of influence, and applying, for at least one relevance score included in the plurality of relevance scores, the weight to generate a weighted relevance score.

15. The one or more non-transitory computer-readable media of any of clauses 11-14, further comprising instructions that, when executed by the one or more processors, cause the one or more processors to perform the steps of detecting an update to the prompt volume, detecting a user input indicating a request to update the at least one candidate action from the plurality of candidate actions, in response to the user input and the update to the prompt volume, updating the relevance scores for the plurality of candidate actions to generate a plurality of updated relevance scores, selecting an updated set of candidate actions based on the updated relevance scores, and modifying the recommendation window to display at least one candidate action from the updated set of candidate actions.

16. The one or more non-transitory computer-readable media of any of clauses 11-15, where generating the plurality of candidate actions comprises identifying, in an external data source, information associated with the one or more design object, and generating one or more candidate actions for accessing the information at the external data source, where the one or more candidate actions are included in the plurality of candidate actions.

17. The one or more non-transitory computer-readable media of any of clauses 11-16, where the one or more design objects are components of an overall design, and the plurality of candidate actions is generated based at least on both the overall design and the one or more design objects.

18. The one or more non-transitory computer-readable media of any of clauses 11-17, where generating a plurality of candidate actions comprises retrieving, from a local data source, a prompt associated with the one or more design objects, generating a candidate action for transmitting the prompt to a trained machine learning (ML) model to generate an updated design object based on the prompt, where the candidate action is included in the plurality of candidate actions.

19. The one or more non-transitory computer-readable media of any of clauses 11-18, where the plurality of candidate actions includes at least one of substituting a first design object of the one or more design objects with an alternative design object, generating an additional design object to complement the first design object, changing an attribute of the first design object, transmitting a prompt associated with the first design object, or accessing information associated with the first design object from an external data source.

20. In various embodiments, a system comprises one or more memories storing instructions, and one or more processors coupled to the one or more memories that, when executing the instructions, perform the steps of receiving a selection of a prompt volume within a design space, where the design space is generated by a design exploration application, and the prompt volume defines a sphere of influence within the prompt volume, identifying one or more design objects within the prompt volume, generating a plurality of candidate actions associated with the one or more design objects, and displaying, within a recommendation window included in the design space, at least one candidate action from the plurality of candidate actions.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating recommendations for a generative design, the method comprising:
receiving a selection of a prompt volume within a design space, wherein the design space is generated by a design exploration application, and the prompt volume defines a sphere of influence within the prompt volume;
identifying one or more design objects within the prompt volume;
generating a plurality of candidate actions associated with the one or more design objects; and
displaying, within a recommendation window included in the design space, at least one candidate action from the plurality of candidate actions.

2. The computer-implemented method of claim 1, further comprising, for each candidate action included in the plurality of candidate actions, generating a relevance score to generate a plurality of relevance scores.

3. The computer-implemented method of claim 2, further comprising:
determining, for each design object included in the one or more design objects, a weight to generate a set of weights; and
applying, for each relevance score included in the plurality of relevance scores, at least one weight in the set of weights to generate a plurality of weighted relevance scores.

4. The computer-implemented method of claim 2, further comprising:
determining a weight for a portion of the sphere of influence; and
applying, for at least one relevance score included in the plurality of relevance scores, the weight to generate a weighted relevance score.

5. The computer-implemented method of claim 2, further comprising:
determining an update to the prompt volume;
updating, based on the update to the prompt volume, the relevance scores for the plurality of candidate actions to generate a plurality of updated relevance scores;
selecting an updated set of candidate actions based on the updated relevance scores; and
modifying the recommendation window to display at least one candidate action from the updated set of candidate actions.

6. The computer-implemented method of claim 2, further comprising:
detecting a user input indicating a request to update the at least one candidate action from the plurality of candidate actions;
in response to the user input, updating the relevance scores for the plurality of candidate actions;
selecting an updated set of candidate actions based on the updated relevance scores; and
modifying the recommendation window to display at least one candidate action from the updated set of candidate actions.

7. The computer-implemented method of claim 1, wherein generating a plurality of candidate actions comprises:
retrieving, from a local data source, a prompt associated with the one or more design objects;
generating a candidate action for transmitting the prompt to a trained machine learning (ML) model to generate an updated design object based on the prompt, wherein the candidate action is included in the plurality of candidate actions.

8. The computer-implemented method of claim 1, wherein the plurality of candidate actions includes at least one of:
substituting a first design object of the one or more design objects with an alternative design object;
generating an additional design object to complement the first design object;
changing an attribute of the first design object;
transmitting a prompt associated with the first design object; or
accessing information associated with the first design object from an external data source.

9. The computer-implemented method of claim 1, further comprising:
attaching the recommendation window to a first design object included in the one or more design objects;
detecting that the first design object has moved; and
in response, moving the recommendation window to a new location within the design space.

10. The computer-implemented method of claim 1, further comprising attaching the recommendation window to an anchor location within the design space.

11. One or more non-transitory computer-readable media including instructions that, when executed by one or more processors, cause the one or more processors to generate design content by performing the steps of:
receiving a selection of a prompt volume within a design space, wherein the design space is generated by a design exploration application, and the prompt volume defines a sphere of influence within the prompt volume;
identifying one or more design objects within the prompt volume;
generating a plurality of candidate actions associated with the one or more design objects; and
displaying, within a recommendation window included in the design space, at least one candidate action from the plurality of candidate actions.

12. The one or more non-transitory computer-readable media of claim 11, further comprising instructions that, when executed by the one or more processors, cause the one or more processors to perform the step of, for each candidate action included in the plurality of candidate actions, generating a relevance score to generate a plurality of relevance scores.

13. The one or more non-transitory computer-readable media of claim 12, further comprising instructions that, when executed by the one or more processors, cause the one or more processors to perform the steps of:
determining, for each design object included in the one or more design objects, a weight to generate a set of weights; and
applying, for each relevance score included in the plurality of relevance scores, at least one weight in the set of weights to generate a plurality of weighted relevance scores.

14. The one or more non-transitory computer-readable media of claim 12, further comprising instructions that, when executed by the one or more processors, cause the one or more processors to perform the steps of:
determining a weight for a portion of the sphere of influence; and
applying, for at least one relevance score included in the plurality of relevance scores, the weight to generate a weighted relevance score.

15. The one or more non-transitory computer-readable media of claim 12, further comprising instructions that, when executed by the one or more processors, cause the one or more processors to perform the steps of:
detecting an update to the prompt volume;
detecting a user input indicating a request to update the at least one candidate action from the plurality of candidate actions;
in response to the user input and the update to the prompt volume, updating the relevance scores for the plurality of candidate actions to generate a plurality of updated relevance scores;
selecting an updated set of candidate actions based on the updated relevance scores; and
modifying the recommendation window to display at least one candidate action from the updated set of candidate actions.

16. The one or more non-transitory computer-readable media of claim 11, wherein generating the plurality of candidate actions comprises:
identifying, in an external data source, information associated with the one or more design objects; and
generating one or more candidate actions for accessing the information at the external data source, wherein the one or more candidate actions are included in the plurality of candidate actions.

17. The one or more non-transitory computer-readable media of claim 11, wherein the one or more design objects are components of an overall design, and the plurality of candidate actions is generated based at least on both the overall design and the one or more design objects.

18. The one or more non-transitory computer-readable media of claim 11, wherein generating a plurality of candidate actions comprises:
retrieving, from a local data source, a prompt associated with the one or more design objects;
generating a candidate action for transmitting the prompt to a trained machine learning (ML) model to generate an updated design object based on the prompt, wherein the candidate action is included in the plurality of candidate actions.

19. The one or more non-transitory computer-readable media of claim 11, wherein the plurality of candidate actions includes at least one of:
substituting a first design object of the one or more design objects with an alternative design object;
generating an additional design object to complement the first design object;
changing an attribute of the first design object;
transmitting a prompt associated with the first design object; or
accessing information associated with the first design object from an external data source.

20. A system comprising:
one or more memories storing instructions; and
one or more processors coupled to the one or more memories that, when executing the instructions, perform the steps of:
receiving a selection of a prompt volume within a design space, wherein the design space is generated by a design exploration application, and the prompt volume defines a sphere of influence within the prompt volume;
identifying one or more design objects within the prompt volume;
generating a plurality of candidate actions associated with the one or more design objects; and
displaying, within a recommendation window included in the design space, at least one candidate action from the plurality of candidate actions.
